(19) United States
(12) Patent Application Publication
(10) Pub. No.: US 2009/0191386 A1
(43) Pub. Date: Jul. 30, 2009

(54) POSITIVE PHOTOSENSITIVE POLYMER COMPOSITION

(75) Inventors: Toshiyuki TAKAHASHI, Ichihara-shi (JP); Eiji WATANABE, Ichihara-shi (JP); Tomohiro ETOU, Ichihara-shi (JP); Yuuki KIMURA, Ichihara-shi (JP)

Correspondence Address: HOGAN & HARTSON LLP;IP GROUP, COLUMBIA SQUARE, 555 THIRTEENTH STREET, N.W., WASHINGTON, DC, 20004, US

(73) Assignee: CHISSO CORPORATION, Osaka (JP)

(21) Appl. No.: 12/353,689

(22) Filed: Jan. 14, 2009

(30) Foreign Application Priority Data
Jan. 15, 2008 (JP) 2008-005515

(51) Int. Cl. B32B 3/10; G03F 7/039

(52) U.S. Cl. 428/195.1; 430/286.1

(57) ABSTRACT

A positive photosensitive polymer composition of the invention contains: a copolymer obtained by the radical polymerization of monomers including a radical polymerizable monomer (a1) having a (meth)acryloyl group and a polyalkylene glycol group a terminal of which is an alkoxy group; and a 1,2-quinone diazide compound. The positive photosensitive polymer composition may further contain a copolymer obtained by the radical polymerization of monomers not including the monomer (a1).

### CROSS REFERENCE TO RELATED APPLICATIONS

This application claims priority under 35 U.S.C. § 119 to Japanese Patent Application No. 2008-005515, filed Jan. 15, 2008, which application is expressly incorporated herein by reference in its entirety.

### BACKGROUND OF THE INVENTION

1. Field of the Invention

The invention relates to a positive photosensitive polymer composition that can be utilized in, for example, a resist field.

2. Description of the Related Art

Patterned transparent films have been used in many parts of display devices as spacers, insulating films, and protective films and so on, and many positive photosensitive polymer compositions have been proposed for those applications (for example, see Patent Documents 1 to 3). In addition, there has been known a positive photosensitive polymer composition containing a polymer using 4-hydroxy styrene as a monomer (for example, see Patent Document 4).

In general, electronic parts, such as thin-film transistor type liquid crystal display devices and solid-state image sensing devices are provided with insulating films for insulation between electric wirings arranged in layers. As a material that forms the insulating film, a positive photosensitive polymer composition that allows the formation of an insulating film having a desired pattern by a small number of steps has been widely used. The positive photosensitive polymer composition is required to have high sensitivity for shortening production time in the process of forming the insulating film. In addition, the positive photosensitive polymer composition is required to have a wide process margin in the process of forming an insulating film. Further, an insulating film or a display device using the positive photosensitive polymer composition is absolutely required in after-treatment of production thereof to be in a contact with a solvent, an acid, an alkali solution, or the like by dipping and to be treated with heat.

| | |
|---|---|
| Patent Document 1 | JP 51-34711 A |
| Patent Document 2 | JP 56-122031 A |
| Patent Document 3 | JP 5-165214 A |
| Patent Document 4 | JP 52-41050 B |

### BRIEF SUMMARY OF THE INVENTION

Under the above-mentioned circumstances, a positive photosensitive polymer composition or the like that allows the formation of a patterned polymer film obtained by developing in an aqueous alkali solution, which has high sensitivity to radiation, is excellent in high solvent resistance, high water resistance, high acid resistance, high alkali resistance, high thermal resistance, high transparency, low dielectric property, adhesiveness with a substrate, i.e., a transparent film on which a pattern is formed (patterned transparent film) has been demanded.

Similarly, a patterned transparent film, an insulating film, a display device, and the like, which are excellent in high solvent resistance, high water resistance, high acid resistance, high alkali resistance, high thermal resistance, high transparency, low dielectric property, adhesiveness with a substrate, and the like, have been also demanded.

The inventors of the invention have found out a positive photosensitive polymer composition containing: a copolymer (A), which is obtained by polymerization of a radical polymerizable monomer (a1) represented by the following formula (I) and another radical polymerizable monomer (a2); and a 1,2-quinone diazide compound (B), and then, the inventors have made this invention based on the finding. The invention includes the following items.

(1) A photosensitive polymer composition, including: a copolymer (A) obtained by polymerizing a radical polymerizable monomer (a1) represented by the following formula (I) and another radical polymerizable monomer (a2); and a 1,2-quinone diazide compound (B).

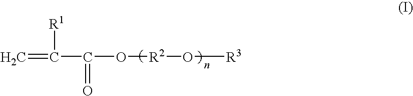

In the formula (I), R¹ represents hydrogen or an alkyl group having 1 to 5 carbon atoms in which arbitrary hydrogen may be replaced by fluorine, R² represents an alkylene group having 1 to 5 carbon atoms, R³ represents an alkyl group having 1 to 10 carbon atoms, and n represents an integer of 1 to 30.

(2) The photosensitive polymer composition according to the item (1), in which the radical polymerizable monomer (a1) includes one or more kinds selected from: methoxy polyethylene glycol (meth)acrylate, ethoxy polyethylene glycol (meth)acrylate, methoxy polypropylene glycol (meth)acrylate, and ethoxy polypropylene glycol (meth)acrylate.

(3) The photosensitive polymer composition according to the item (1) or (2), in which the radical polymerizable monomer (a2) includes one or more kinds selected from: a radical polymerizable monomer having an unsaturated carboxylic acid, a radical polymerizable monomer having an unsaturated carboxylic anhydride, a radical polymerizable monomer having a phenolic OH, a radical polymerizable monomer having an epoxy, a radical polymerizable monomer represented by the following formula (III), a radical polymerizable monomer containing an N-substituted maleimide, and a radical polymerizable monomer containing a dicyclopentanyl.

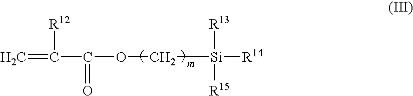

In the formula (III), R¹² represents hydrogen or an alkyl group having 1 to 5 carbon atoms in which arbitrary hydrogen may be replaced by fluorine, R¹³, R¹⁴, and R¹⁵ each represent a hydroxyl group, an alkyl group having 1 to 5 carbon atoms, an alkoxy group having 1 to 5 carbon atoms, or —O—(Si(CⱼH₂ⱼ₊₁)₂O)ₚSi(CₖH₂ₖ₊₁)₃, j represents an integer of 1 to 5, k represents an integer of 1 to 5, p represents 0 or an integer of 1 to 10, and m represents an integer of 1 to 5.

(4) The photosensitive polymer composition according to the item (3), in which the radical polymerizable monomer having an unsaturated carboxylic acid is (meth)acrylic acid.

(5) The photosensitive polymer composition according to the item (3) or (4), in which the radical polymerizable monomer having an unsaturated carboxylic anhydride is maleic anhydride.

(6) The photosensitive polymer composition according to any one of the items (3) to (5), in which the radical polymerizable monomer having a phenolic OH is one or both of hydroxystyrene and a compound represented by the following formula (II).

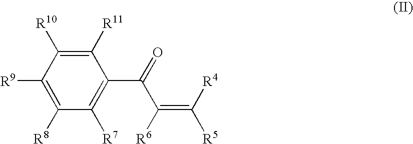

In the formula (II), R⁴, R⁵, and R⁶ each represent hydrogen or an alkyl group having 1 to 3 carbon atoms in which arbitrary hydrogen may be replaced by fluorine, R⁷, R⁸, R⁹, R¹⁰, and R¹¹ each represent hydrogen, a halogen, —CN, —CF₃, —OCF₃, —OH, an alkyl group having 1 to 5 carbon atoms in which arbitrary —CH₂— may be replaced by —COO—, —OCO—, or —CO— and arbitrary hydrogen may be replaced by a halogen, or an alkoxy group having 1 to 5 carbon atoms in which arbitrary hydrogen may be replaced by a halogen, provided that one or more of R⁷ to R¹¹ represents —OH.

(7) The photosensitive polymer composition according to the item (6), in which the compound represented by the formula (II) is 4-hydroxyphenyl vinyl ketone.

(8) The photosensitive polymer composition according to any one of the items (3) to (7), in which the radical polymerizable monomer having an epoxy is one or more kinds selected from: glycidyl (meth)acrylate, methylglycidyl (meth)acrylate, 3,4-epoxycyclohexylmethyl (meth)acrylate, (3-methyl-3-oxetanyl)methyl (meth)acrylate, (3-ethyl-3-oxetanyl)methyl (meth)acrylate, (3-methyl-3-oxetanyl)ethyl (meth)acrylate, and (3-ethyl-3-oxetanyl)ethyl (meth)acrylate.

(9) The photosensitive polymer composition according to any one of the items (3) to (8), in which the radical polymerizable monomer containing an N-substituted maleimide is one or more kinds selected from: N-methylmaleimide, N-ethylmaleimide, N-butylmaleimide, N-cyclohexylmaleimide, N-benzylmaleimide, N-phenylmaleimide, N-(4-acetylphenyl)maleimide, N-(2,6-diethylphenyl)maleimide, N-(4-dimethylamino-3,5-dinitrophenyl)maleimide, N-(1-anilinonaphthyl-4)maleimide, N-[4-(2-benzoxazolyl)phenyl]maleimide, and N-(9-acridinyl)maleimide.

(10) The photosensitive polymer composition according to any one of the items (3) to (9), in which the radical polymerizable monomer containing a dicyclopentanyl is dicyclopentanyl (meth)acrylate.

(11) The photosensitive polymer composition according to any one of the items (1) to (10), in which the 1,2-quinone diazide compound (B) is a condensation product of 4,4′-[1-[4-[1-[4-hydroxyphenyl]-1-methylethyl]phenyl]ethylidene]bisphenol and 1,2-naphthoquinone diazide-5-sulfonic acid chloride.

(12) The photosensitive polymer composition according to any one of the items (1) to (11), further including a compound having an epoxy.

(13) The photosensitive polymer composition according to any one of the items (1) to (12), further including a copolymer (C) obtained by polymerizing two or more kinds of the radical polymerizable monomers (a2).

(14) The photosensitive polymer composition according to the item (13), in which the radical polymerizable monomers (a2) in the copolymer (C) include the radical polymerizable monomer (a2) according to any one of the items (3) to (10).

(15) The photosensitive polymer composition according to any one of the items (1) to (14), further including a hindered phenol antioxidant.

(16) A patterned transparent film obtained by exposure to an applied film of the photosensitive polymer composition according to any one of the items (1) to (15) through a mask having openings in accordance with a desired pattern, development, and baking.

(17) A patterned transparent film obtained by exposure to an applied film of the photosensitive polymer composition according to any one of the items (1) to (15) through a mask having openings in accordance with a desired pattern, development, postexposure, and baking.

(18) The patterned transparent film according to the item (16) or (17), in which the patterned transparent film is an insulating film.

(19) A display device including the patterned transparent film according to any one of the items (16) to (18).

In the description of the invention, for representing one or both an acrylic acid and a methacrylic acid, they may be uniformly described as “(meth)acrylic acid”. In addition, for representing one or both an acrylate and a methacrylate in a similar manner, they may be uniformly described as “(meth)acrylate”.

“Alkyl” in the description of the invention refers to a linear chain or a branched chain alkyl. Examples thereof include a methyl, ethyl, propyl, n-butyl, t-butyl, pentyl, and hexyl groups.

According to the invention, there can be provided, in particular, a photosensitive polymer composition having high sensitivity, a transparent film formed of the photosensitive polymer composition, and a display device having the transparent film.

### DETAILED DESCRIPTION OF THE INVENTION

### 1. Photosensitive Polymer Composition of the Invention

A photosensitive polymer composition of the invention contains: a copolymer (A) obtained by polymerizing a radical polymerizable monomer (a1) represented by the following formula (I) and another radical polymerizable monomer (a2); and a 1,2-quinone diazide compound (B). The number of kinds of the copolymer (A) may be one or two or more. In addition, the number of kinds of the 1,2-quinone diazide compound (B) may also be one or two or more.

<1-1. Copolymer (A)>

The copolymer (A) of the invention is a polymer obtained by polymerizing the radical polymerizable monomer (a1) represented by the following formula (I) and the other radical polymerizable monomer (a2). That is, the copolymer (A) is a copolymer obtained by polymerizing a mixture of monomers including the radical polymerizable monomer (a1).

In the copolymer (A), the number of kinds of the radical polymerizable monomer (a1) represented by the formula (I) may be one or two or more. The content of the radical polymerizable monomer (a1) in all monomers of the copolymer (A) is preferably 0.1 to 40 wt % in order that a difference in solubility in an alkali aqueous solution between an unexposed portion and an exposed portion in an applied film of the photosensitive polymer composition may be enlarged, that is, the sensitivity of the photosensitive polymer composition to radiation may be improved; the content is more preferably 1 to 20 wt %.

In the copolymer (A), the number of kinds of the radical polymerizable monomer (a2) may be one or two or more. The content of the radical polymerizable monomer (a2) in all monomers of the copolymer (A) is preferably 60 to 99.9 wt % in order that the photosensitive polymer composition of the invention may exert characteristics provided by the radical polymerizable monomer (a2); the content is more preferably 80 to 99 wt %.

<1-1-1. Radical Polymerizable Monomer (a1) Represented by Formula (I)>

The radical polymerizable monomer (a1) is represented by the following formula (I).

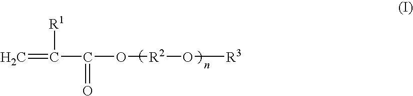

In the formula (I), R¹ represents hydrogen or an alkyl group having 1 to 5 carbon atoms in which arbitrary hydrogen may be replaced by fluorine, R² independently represents an alkylene group having 1 to 5 carbon atoms, R³ represents an alkyl group having 1 to 10 carbon atoms, and n represents an integer of 1 to 30.

Examples of the radical polymerizable monomer (a1) (which may hereinafter be referred to as “monomer (a1)”) includes methoxy polyethylene glycol (meth)acrylate, ethoxy polyethylene glycol (meth)acrylate, methoxy polypropylene glycol (meth)acrylate, and ethoxy polypropylene glycol (meth)acrylate.

Each of those radical polymerizable monomers (a1) is preferable because each of them can significantly improve the solubility of the exposed portion in the transparent film of the invention to be described later in an alkali aqueous solution as compared to the solubility of the unexposed portion in the transparent film in the alkali aqueous solution. That is, any one of those radical polymerizable monomers (a1) is preferably used because of the following reason: the pattern size of a hole or the like in the exposed portion can be enlarged while the thickness of the unexposed portion after development remains nearly unchanged, so the photosensitive polymer composition can obtain high sensitivity to radiation.

<1-1-2. Another Radical Polymerizable Monomer (a2)>

The radical polymerizable monomer (a2) has only to be a radical polymerizable monomer except the radical polymerizable monomer (a1), and can be selected from the following viewpoint: the photosensitive polymer composition can exert desired characteristics in accordance with its applications. Examples of the radical polymerizable monomer (a2) (which may hereinafter be referred to as “monomer (a2)”) include a radical polymerizable monomer having an acidic group, a radical polymerizable monomer having an epoxy, a radical polymerizable monomer containing silicon, a radical polymerizable monomer containing an N-substituted maleimide, and a radical polymerizable monomer containing a dicyclopentanyl.

<1-1-2-1. Radical Polymerizable Monomer (a2) Having Acidic Group>

The radical polymerizable monomer having an acidic group is a monomer constituting the copolymer (A) so that the copolymer (A) may have the acidic group. The content of the radical polymerizable monomer having an acidic group is preferably 5 to 80 wt % in all monomers of the radical polymerizable monomers (a2) in order that the photosensitive polymer composition may exert sufficient developing property.

Examples of the radical polymerizable monomer having an acidic group include a radical polymerizable monomer having an unsaturated carboxylic acid, a radical polymerizable monomer having an unsaturated carboxylic anhydride, and a radical polymerizable monomer having a phenolic OH. Example of the radical polymerizable monomer having an unsaturated carboxylic acid includes (meth)acrylic acid. Example of the radical polymerizable monomer having an unsaturated carboxylic anhydride includes maleic anhydride. Examples of the radical polymerizable monomer having a phenolic OH include hydroxystyrene and a radical polymerizable monomer represented by the following formula (II).

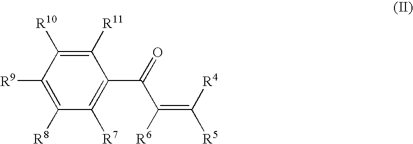

In the formula (II), R⁴, R⁵, and R⁶ each represent hydrogen or an alkyl group having 1 to 3 carbon atoms in which arbitrary hydrogen may be replaced by fluorine, R⁷, R⁸, R⁹, R¹⁰, and R¹¹ each represent hydrogen, a halogen, —CN, —CF₃, —OCF₃, —OH, an alkyl group having 1 to 5 carbon atoms in which arbitrary —CH₂— may be replaced by —COO—, —OCO—, or —CO— and arbitrary hydrogen may be replaced by a halogen, or an alkoxy group having 1 to 5 carbon atoms in which arbitrary hydrogen may be replaced by a halogen, provided that at least one of R⁷ to R¹¹ represents —OH.

Example of the radical polymerizable monomer represented by the formula (II) includes 4-hydroxyphenyl vinyl ketone.

Each of the above-mentioned specific examples of the radical polymerizable monomer having an acidic group is preferable from the viewpoint of the achievement of good alkali solubility.

Of the above specific examples, methacrylic acid, hydroxystyrene, and 4-hydroxyphenyl vinyl ketone are preferable. Methacrylic acid and hydroxystyrene are preferable because of their ease of availability. 4-hydroxyphenyl vinyl ketone is preferable because of its high heat resistance and high transparency. Further, methacrylic acid is more preferable from the viewpoint of an improvement in solubility of the exposed portion in an alkali aqueous solution at the time of development, that is, developing property.

<1-1-2-2. Radical Polymerizable Monomer (a2) Having Epoxy>

The radical polymerizable monomer having an epoxy is a radical polymerizable monomer having a cyclic ether group. The content of the radical polymerizable monomer having an epoxy is preferably 10 to 80 wt % in all monomers of the radical polymerizable monomers (a2) from the viewpoint of an improvement in heat resistance of the transparent film of the invention.

Examples of the radical polymerizable monomer having an epoxy include glycidyl (meth)acrylate, methylglycidyl (meth)acrylate, α-ethyl acrylate glycidyl ester-3,4-epoxycyclohexyl (meth)acrylate, (3-methyl-3-oxetanyl)methyl (meth)acrylate, (3-ethyl-3-oxetanyl)methyl (meth)acrylate, (3-methyl-3-oxetanyl)ethyl (meth)acrylate, and (3-ethyl-3-oxetanyl)ethyl (meth)acrylate. Each of those radical polymerizable monomers is preferable in order that the transparent film may show good heat resistance and improved transparency.

Of those, specific examples, glycidyl (meth)acrylate, methyl glycidyl (meth)acrylate, 3,4-epoxycyclohexylmethyl (meth)acrylate, and (3-ethyl-3-oxetanyl)methyl (meth)acrylate are easily obtainable and the resulting patterned transparent films are preferable in terms of improving solvent resistance, water resistance, acid resistance, alkali resistance, thermal resistance, and transparency.

<1-1-2-3. Radical Polymerizable Monomer (a2) Containing Silicon>

The radical polymerizable monomer containing silicon is a monomer in which part of the carbon atoms of the main chain are each, or preferably a carbon atom at a terminal of the main chain is, replaced by silicon. The content of the radical polymerizable monomer containing silicon is preferably 10 to 80 wt % in all monomers of the radical polymerizable monomers (a2) from the viewpoint of the suppression of the deterioration of the characteristics in the photosensitive polymer composition of the invention at high temperatures.

Example of the radical polymerizable monomer containing silicon includes a radical polymerizable monomer represented by the following formula (III).

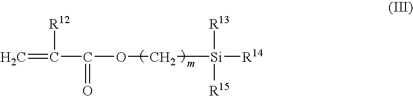

In the formula (III), R¹² represents hydrogen or an alkyl group having 1 to 5 carbon atoms in which arbitrary hydrogen may be replaced by fluorine, R¹³, R¹⁴, and R¹⁵ each represent a hydroxyl group, an alkyl group having 1 to 5 carbon atoms, an alkoxy group having 1 to 5 carbon atoms, or —O—(Si(CⱼH₂ⱼ₊₁)₂O)ₚSi(CₖH₂ₖ₊₁)₃, j represents an integer of 1 to 5, k represents an integer of 1 to 5, p represents 0 or an integer of 1 to 10, and m represents an integer of 1 to 5.

The radical polymerizable monomer represented by the formula (III) is preferable because the transparency of the transparent film is high, and hardly deteriorates owing to baking at high temperatures. Examples of the radical polymerizable monomer represented by the formula (III) include 3-methacryloxypropyltrimethoxysilane and methacryloyloxypropyl-tris-trimethylsiloxysilane.

<1-1-2-4. Radical Polymerizable Monomer (a2) Containing N-Substituted Maleimide>

The radical polymerizable monomer containing an N-substituted maleimide is a compound having the following characteristic: a double bond of the maleimide is subjected to radical polymerization in the production of the copolymer (A). The content of the radical polymerizable monomer containing an N-substituted maleimide is preferably 5 to 70 wt % in all monomers of the radical polymerizable monomers (a2) in order that the transparent film may show improved heat resistance and low dielectric property.

Examples of the radical polymerizable monomer having an N-substituted maleimide include N-methylmaleimide, N-ethylmaleimide, N-butylmaleimide, N-cyclohexylmaleimide, N-benzylmaleimide, N-phenylmaleimide, N-(4-acetylphenyl)maleimide, N-(2,6-diethylphenyl)maleimide, N-(4-dimethylamino-3,5-dinitrophenyl)maleimide, N-(1-anilinonaphthyl-4-)maleimide, N-[4-(2-benzoxazolyl)phenyl]maleimide, and N-(9-acridinyl)maleimide.

<1-1-2-5. Radical Polymerizable Monomer (a2) Containing Dicyclopentanyl>

The radical polymerizable monomer containing a dicyclopentanyl is a compound having a dicyclopentanyl and a radical polymerizable group. The content of the radical polymerizable monomer containing a dicyclopentanyl is preferably 5 to 70 wt % in all monomers of the radical polymerizable monomers (a2) in order that the transparent film may show improved heat resistance and low dielectric property.

Examples of the radical polymerizable monomer containing a dicyclopentanyl include dicyclopentanyl acrylate and dicyclopentanyl methacrylate.

<1-1-2-6. Other Components>

The copolymer (A) may contain a radical polymerizable monomer except the above-mentioned radical polymerizable monomers as the other radical polymerizable monomer (a2). The content of the other radical polymerizable monomer is preferably 1 to 50 wt % in order that the other radical polymerizable monomer may exert its characteristics without impairing an effect of the invention. Examples of the other radical polymerizable monomer include: compounds each having an aromatic group and a radical polymerizable group such as styrene; and unsaturated carboxylates such as methyl (meth)acrylate.

A preferable example of the copolymer (A) is a copolymer which contains the radical polymerizable monomer (a1), the radical polymerizable monomer having a phenolic OH, and the radical polymerizable monomer having an epoxy as monomers, and which may further contain the radical polymerizable monomer containing silicon, the radical polymerizable monomer containing an N-substituted maleimide, and the radical polymerizable monomer containing a dicyclopentanyl as monomers.

Another preferable example of the copolymer (A) is a composition formed of: a copolymer (A1) using the radical polymerizable monomer (a1), the radical polymerizable monomer having an unsaturated carboxylic acid, the radical polymerizable monomer containing an N-substituted maleimide, and the radical polymerizable monomer containing a dicyclopentanyl as monomers; and a copolymer (A2) using the radical polymerizable monomer (a1), the radical polymerizable monomer having a phenolic OH, the radical polymerizable monomer having an epoxy, and the radical polymerizable monomer containing silicon as monomers.

Still another preferable example of the copolymer (A) is a composition formed of: a copolymer (A3) which contains the radical polymerizable monomer (a1), and one or both of the radical polymerizable monomer having an unsaturated carboxylic acid and the radical polymerizable monomer having a phenolic OH as monomers, and which may further contain the radical polymerizable monomer containing silicon, the radical polymerizable monomer containing an N-substituted maleimide, and the radical polymerizable monomer containing a dicyclopentanyl as monomers; and a copolymer (A4) which contains the radical polymerizable monomer (a1) and the radical polymerizable monomer having an epoxy as monomers, and which may further contain the radical polymerizable monomer having a phenolic OH, the radical polymerizable monomer containing silicon, the radical polymerizable monomer containing an N-substituted maleimide, and the radical polymerizable monomer containing a dicyclopentanyl as monomers.

<1-2. Quinone Diazide Compound (B)>

In 1,2-quinone diazide compound (B), for example, any compound used as a photosensitizing agent in the field of resist technology can be employed. Examples of the 1,2-quinone diazide compound (B) include an ester of a phenol compound with 1,2-benzoquinone diazide-4-sulfonic acid or 1,2-benzoquinone diazide-5-sulfonic acid, an ester of a phenol compound with 1,2-naphthoquinone diazide-4-sulfonic acid or 1,2-naphthoquinone diazide-5-sulfonic acid, an sulfonamide of a compound in which a hydroxyl group of a phenol compound is replaced by an amino group with 1,2-benzoquinone diazide-4-sulfonic acid or 1,2-benzoquinone diazide-5-sulfonic acid, and an sulfonamide of a compound in which a hydroxyl group of a phenol compound is replaced by an amino group with 1,2-naphthoquinone diazide-4-sulfonic acid or 1,2-naphthoquinone diazide-5-sulfonic acid. These compounds may be used alone or in combination of two or more.

Specific examples of the phenol compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiinden-5,6,7,5′,6′,7′-hexanol, and 2,2,4-trimethyl-7,2′,4′-trihydroxyflavan.

In particular, in terms of increasing transparency of the positive photosensitive polymer composition of the invention, it is preferable to use, as 1,2-quinone diazide compound (B), an ester of 2,3,4-trihydroxybenzophenone with 1,2-naphthoquinone diazide-4-sulfonic acid, an ester of 2,3,4-trihydroxybenzophenone with 1,2-naphthoquinone diazide-5-sulfonic acid, an ester of 4,4′-[1-[4-[1-[4-hydroxyphenyl]-1-methylethyl]phenyl]ethylidene]bisphenol with 1,2-naphthoquinone diazide-4-sulfonic acid, and an ester of 4,4′-[1-[4-[1-[4-hydroxyphenyl]-1-methylethyl]phenyl]ethylidene]bisphenol with 1,2-naphthoquinone diazide-5-sulfonic acid. Those may be used singly or two or more thereof may be used in combination.

The content of the 1,2-quinone diazide compound (B) in the positive photosensitive polymer composition of the invention, is 5 to 50 parts by weight with respect to the total 100 parts by weight of the polymer component including copolymer (A).

<1-3. Additional Component>

The photosensitive polymer composition of the invention may further contain a component except the copolymer (A) and the 1,2-quinone diazide compound (B) described above from the viewpoint of the impartment of additional characteristics. Examples of such additional component include a copolymer (C) as a copolymer except the copolymer (A), a solvent, an additive, a polyvalent carboxylic acid, and an epoxy compound.

<1-3-1. Copolymer (C)>

The copolymer (C) is a copolymer obtained by polymerizing two or more kinds of the radical polymerizable monomers (a2). The number of kinds of the copolymer (C) may be one or two or more. The radical polymerizable monomers (a2) as the monomers of the copolymer (C) can be used as follows to provide the copolymer (C): the monomers are used at a content ratio in the foregoing range in the copolymer (A) except that the radical polymerizable monomer (a1) represented by the formula (I) is omitted. The copolymer (C) is preferably incorporated from the viewpoints of: the kinds of characteristics exerted by the radical polymerizable monomers (a2) such as transparency, the suppression of the deterioration of the transparency at the time of heating, low dielectric property, solvent resistance, high water resistance, high acid resistance, and high alkali resistance; and the adjustment of the strength of the characteristics exerted by the radical polymerizable monomers (a2).

For example, radical polymerizable monomers except the radical polymerizable monomer (a2) used in the copolymer (A) are preferably used as the radical polymerizable monomers (a2) in the copolymer (C) because the photosensitive polymer composition can exert an additionally large number of characteristics based on the radical polymerizable monomers. Radical polymerizable monomers each of which is identical to, or of the same kind of, the radical polymerizable monomer (a2) used in the copolymer (A) are also preferably used as the radical polymerizable monomers (a2) in the copolymer (C) because the photosensitive polymer composition can exert the characteristics specific to the radical polymerizable monomers in an additionally strong fashion.

A preferable example of a combination of the copolymer (A) and the copolymer (C) is a composition formed of: the copolymer (A) which contains the radical polymerizable monomer (a1) and the radical polymerizable monomer having an unsaturated carboxylic acid as monomers, and which may further contain the radical polymerizable monomer having a phenolic OH, the radical polymerizable monomer containing silicon, the radical polymerizable monomer containing an N-substituted maleimide, and the radical polymerizable monomer containing a dicyclopentanyl as monomers; and the copolymer (C) which contains the radical polymerizable monomer having an epoxy as a monomer, and which may further contain the radical polymerizable monomer having a phenolic OH, the radical polymerizable monomer containing silicon, the radical polymerizable monomer containing an N-substituted maleimide, and the radical polymerizable monomer containing a dicyclopentanyl as monomers.

In addition, a preferable example of a combination of the copolymer (A) and the copolymer (C) is a composition formed of: the copolymer (A) which contains the radical polymerizable monomer (a1) and the radical polymerizable monomer having an epoxy as monomers, and which may further contain the radical polymerizable monomer having a phenolic OH, the radical polymerizable monomer containing silicon, the radical polymerizable monomer containing an N-substituted maleimide, and the radical polymerizable monomer containing a dicyclopentanyl as monomers; and the copolymer (C) which contains the radical polymerizable monomer having an unsaturated carboxylic acid as a monomer, and which may further contain the radical polymerizable monomer having a phenolic OH, the radical polymerizable monomer containing silicon, the radical polymerizable monomer containing an N-substituted maleimide, and the radical polymerizable monomer containing a dicyclopentanyl as monomers.

<1-3-2. Solvent>

The solvent is preferably a solvent capable of dissolving the copolymer (A) and the 1,2-quinone diazide compound (B), and, if the photosensitive polymer composition contains the copolymer (C), the copolymer (C). The number of kinds of the solvent may be one or two or more.

Further, the solvent is preferably a compound having a boiling point of 100° C. to 300° C. Specific examples of the solvent having a boiling point of 100° C. to 300° C. include water, butyl acetate, butyl propionate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, methyl 3-oxypropionate, ethyl 3-oxypropionate, methyl 3-methoxypropionate, ethyl 3-methoxypropionate, methyl 3-ethoxypropionate, ethyl 3-ethoxypropionate, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanate, ethyl 2-oxobutanate, dioxane, ethyleneglycol, diethyleneglycol, triethyleneglycol, propyleneglycol, dipropyleneglycol, tripropyleneglycol, 1,4-butanediol, ethyleneglycol monoisopropyl ether, ethyleneglycol monobutyl ether, propyleneglycol monomethyl ether, propyleneglycol monomethyl ether acetate, propyleneglycol monoethyl ether acetate, propyleneglycol monopropyl ether acetate, ethyleneglycol monobutyl ether acetate, cyclohexanone, cyclopentanone, diethyleneglycol monomethyl ether, diethyleneglycol monomethyl ether acetate, diethyleneglycol monoethyl ether, diethyleneglycol monoethyl ether acetate, diethyleneglycol monobutyl ether, diethyleneglycol monobutyl ether acetate, diethyleneglycol dimethyl ether, diethyleneglycol diethyl ether, diethyleneglycol methylethyl ether, toluene, xylene, γ-butyrolactone, and N,N-dimethyl acetamide.

The solvent may be any mixture solvent containing 20 wt % or more of a solvent with boiling points of 100 to 300° C. As a solvent other than any of the above mixture solvents with the above boiling points of 100 to 300° C., one or two or more of known solvents other than the above solvents can be used.

The solvent is preferably one or more selected from the group consisting of propylene glycol monomethyl ether, propylene glycol monomethyl ether acetate, propylene glycol monoethyl ether acetate, methyl 3-methoxypropionate, ethyl 3-etoxypropionate, diethylene glycol monoethyl ether acetate, diethylene glycol monobutyl ether acetate, diethylene glycol dimethyl ether, diethylene glycol methylethyl ether, ethyl lactate, and butyl acetate in terms of improving coating uniformity of the photosensitive polymer composition. Further, the solvent is preferably one or more selected from the group consisting of propylene glycol monomethyl ether acetate, methyl 3-methoxypropionate, ethyl 3-ethoxypropionate, diethylene glycol methylethyl ether, ethyl lactate, and butyl acetate in terms of improving coating uniformity of the photosensitive polymer composition and the safety of the human body. Further, the solvent is preferably added to the positive photosensitive polymer composition of the invention so that the total amount of the copolymer and the photosensitizing agent, as a solid fraction, is 5 to 50 wt %.

<1-3-3 Additive>

The additive may be added in order to improve characteristics of the photosensitive polymer composition of the invention such as the resolution, coating uniformity, developing performance, adhesiveness, and stability. Examples of the additives include: an acryl, styrene, polyethylene imine, or urethane-based polymer dispersant; an anionic, cationic, nonionic, or fluorine-based surfactant; a silicon polymer-based spreadability improver; an adhesiveness improver such as a silane-coupling agent; a UV absorber such as alkoxybenzophenones; a cohesion inhibitor such as sodium polyacrylate; a thermal crosslinking agent such as an epoxy compound, a melamine compound, or a bis-azide compound; an alkali-solubility accelerator such as an organic carboxylic acid and phenol compound; and an antioxidant such as a hindered phenol.

Specific examples of the additives include Polyflow No. 45, Polyflow-KL-245 Polyflow, No. 75, Polyflow No. 90, and Polyflow No. 95 (all of which are product names that are manufactured by Kyoeisha Chemical Co., Ltd.); Disperbyk 161, Disperbyk 162, Disperbyk 163, Disperbyk 164, Disperbyk 166, Disperbyk 170, Disperbyk 180, Disperbyk 181, Disperbyk 182, BYK300, BYK306, BYK310, BYK320, BYK330, BYK344, and BYK346 (all of which are product names that are manufactured by BYK-Chemic Japan K.K.); KP-341, KP-358, KP-368, KF-96-50CS, and KF-50-100CS (all of which are product names that are manufactured by Shin-Etsu Chemical Co., Ltd.); Surflon SC-101 and Surflon KH-40 (both of which are product names that are manufactured by Seimi Chemical Co., Ltd.); Ftergent 222F, Ftergent 251, and FTX-218 (all of which are product names that are manufactured by Neos Co., Ltd.); EFTOP EF-351, EFTOP EF-352, EFTOP EF-601, EFTOP EF-801, and EFTOP EF-802 (all of which are product names that are manufactured by Mitsubishi Materials Corporation); MEGAFACE F-171, MEGAFACE F-177, MEGAFACE F-475, MEGAFACE R-08, and MEGAFACE R-30 (all of which are product names that are manufactured by Dainippon Ink and Chemicals Incorporated); fluoroalkyl benzenesulfonate, fluoroalkyl carboxylate, fluoroalkyl polyoxyethylene ether, fluoroalkyl ammonium iodide, fluoroalkyl betaine, fluoroalkyl sulfonate, diglycerin tetrakis(fluoroalkyl polyoxy ethylene ether), fluoroalkyl trimethylammonium salt, fluoroalkyl amino sulfonate, polyoxyethylene nonylphenylether, polyoxyethylene octylphenylether, polyoxyethylene alkylether, polyoxyethylene laurylether, polyoxyethylene oleylether, polyoxyethylene tridecylether, polyoxyethylene cetylether, polyoxyethylene stearylether, polyoxyethylene laurate, polyoxyethylene olerate, polyoxyethylene stearate, polyoxyethylene laurylamine, sorbitan laurate, sorbitan palmitate, sorbitan stearate, sorbitan oleate, sorbitan fatty ester, polyoxyethylene sorbitan laurate, polyoxyethylene sorbitan palmitate, polyoxyethylene sorbitan stearate, polyoxyethylene sorbitan oleate, polyoxyethylene naphtylether, alkylbenzene sulfonate salt, and alkyldiphenylether disulfonate. One or more of those may preferably be chosen to be used in the above-mentioned additive.

Of those additives, the addition of one or more selected from: fluorine-based surfactants such as fluoroalkyl benzene sulfonate, fluoroalkyl carboxylate, fluoroalkyl polyoxyethylene ether, fluoroalkyl ammonium iodide, fluoroalkyl betaine, fluoroalkyl sulfonate, diglycerol tetrakis(fluoroalkyl polyoxyethylene ether), fluoroalkyl trimethyl ammonium salt, and fluoroakyl aminosulfonate; and silicon polymer-based spreadability improvers such as BYK306, BYK344, BYK346, KP-341, KP-358, and KP-368, is preferable in terms of improving coating uniformity of a photosensitive polymer composition.

As described in Japanese Patent No. 3919147, a known compound such as: a compound which has a t-butyl group at its o-position with respect to its phenolic OH and which may further have a substituent such as an alkyl group; or a dimer, trimer, or tetramer of the compound obtained by bonding two to four molecules of the compound through a divalent organic group at the p-position of each of the molecules is used as the hindered phenol antioxidant. Example of a commercially available product to be used as such antioxidant includes an Irganox 1010 (product name, Ciba Japan K.K.) mainly formed of a compound represented by the following formula. The hindered phenol antioxidant is added to the photosensitive polymer composition in an amount of, for example, about 1 to 20 parts by weight with respect to 100 parts by weight of the copolymer component for suppressing a change in color of the photosensitive polymer composition.

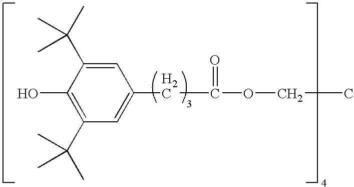

<1-3-4. Polyvalent Carboxylic Acid>

The polyvalent carboxylic acid is preferable because, at the time of the storage of the photosensitive polymer composition of the invention, the polyvalent carboxylic acid suppresses the decomposition of the 1,2-quinone diazide compound (B), and prevents the coloring of the photosensitive polymer composition. In addition, when the photosensitive polymer composition of the invention contains an epoxy, a carboxyl group of the polyvalent carboxylic acid reacts with the epoxy by heating. Therefore, the polyvalent carboxylic acid is preferable from the viewpoints of additional improvements in heat resistance and chemical resistance of the transparent film.

Examples of the polycarboxylic acid may include trimellitic anhydride, phthalic anhydride, and 4-methyl cyclohexane-1,2-dicarboxylic acid anhydride. Of those polycarboxylic acids, trimellitic anhydride is preferable.

The content of the polyvalent carboxylic acid is preferably 1 to 30 parts by weight, or more preferably 2 to 20 parts by weight with respect to 100 parts by weight of the total amount of the copolymer component in the photosensitive polymer composition of the invention.

<1-3-5. Epoxy Compound>

The epoxy compound can be further added to the photosensitive polymer composition from the viewpoint of, for example, an improvement in durability of the transparent film. The epoxy compound is not particularly limited so long as the compound has the epoxy, and the number of kinds of the epoxy compound may be one or two or more. The epoxy compound is added at a content of preferably 0.1 to 40 wt %, or more preferably 0.2 to 30 wt % from the viewpoint of an improvement in physical durability of the transparent film.

Examples of the epoxy compound include compounds such as a compound having the radical polymerizable monomer having an epoxy as a monomer such as a homopolymer, a copolymer, and an oligomer; bisphenol A type epoxy resins; glycidyl ester type epoxy resins; alicyclic epoxy resins; and compounds represented by the following formulae (E1) to (E5). It should be noted that n in the formula (E4) represents an integer of 0 to 10.

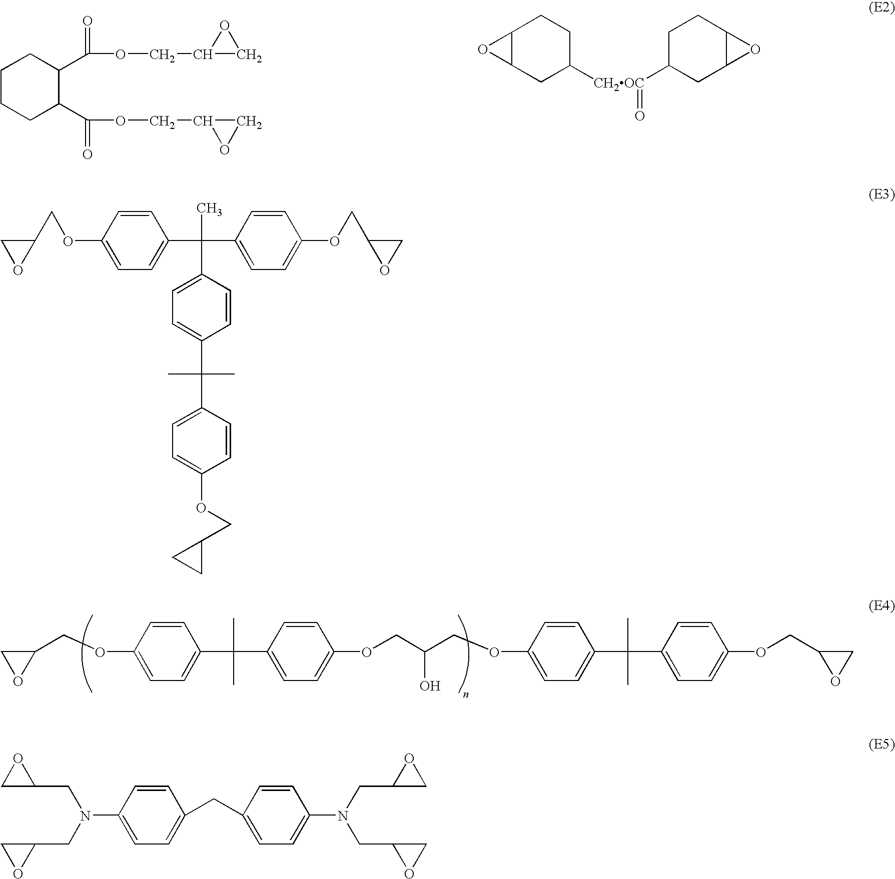

Further, specific examples of the epoxy resin include jER807, jER815, jER825, and jER827 (all of which are product names, Japan Epoxy Resin, Co., Ltd.). As the compound represented by the formula (E1), Araldite CY184 (product name, Ciba Japan K.K.) is exemplified. As the compound represented by the formula (E2), CLLOXIDE 2021P (product name, DAICEL CHEMICAL INDUSTRIES, LTD.) is exemplified. As the compound represented by the formula (E3), TECHMORE VG3101L (product name, Mitsui Chemicals, Inc.) is exemplified. As the compound represented by the formula (E4), jER828, jER190P, jER191P, jER1004, and jER1256 (all of which are product names, Japan Epoxy Resin, Co., Ltd.), Araldite CY177 (product name, Ciba Japan K.K.) are exemplified. As the compound represented by the formula (E5), “4,4′-methylenebis(N,N-diglycidyl aniline)” (SIGMA-ALDRICH Japan K.K.) is exemplified.

Of those, preferred are jER828 (product name, Japan Epoxy Resin, Co., Ltd.) which is the compound represented by the formula (E4) (a mixture of compound where n represents 0 to 4), Araldite CY184 (product name, Ciba Japan K.K.) which is the compound represented by the formula (E1), CLLOXIDE 2021P (product name, DAICEL CHEMICAL INDUSTRIES, LTD.) which is the compound represented by the formula (E2), TECHMORE VG3101L (product name, Mitsui Chemicals, Inc.) which is the compound represented by the formula (E3), and “4,4′-methylenebis(N,N-diglycidyl aniline)” (SIGMA-ALDRICH Japan K.K.), which is the compound represented by the formula (E5) from the viewpoint of improving transparency and smoothness of the transparent film.

<1-4. Polymerization Method for Each of Copolymer (A) and Copolymer (C)>

A polymerization method for each of the copolymer (A) and the copolymer (C) is not particularly limited; radical polymerization in a solution using a solvent is preferable. The temperature at which the polymerization is performed is not particularly limited so long as a polymerization initiator to be used produces a sufficient amount of radicals at the temperature; the temperature typically falls within the range of 50° C. to 150° C. The time period for which the polymerization is performed is not particularly limited either; the time period typically falls within the range of 1 to 24 hours. In addition, the polymerization can be performed under pressure, reduced pressure, or atmospheric pressure.

The solvent, which can be used in the above polymerization reaction, is preferably one that dissolves the radical polymerizable monomers (a1) and (a2), and the copolymers (A) and (C) to be generated. Specific examples of the solvent include methanol, ethanol, 1-propanol, 2-propanol, acetone, 2-butanone, ethyl acetate, propyl acetate, tetrahydrofuran, acetonitrile, dioxane, toluene, xylene, cyclohexanone, ethyleneglycol monoethyl ether, propyleneglycol monomethyl ether, propyleneglycol monomethyl ether acetate, diethyleneglycol dimethyl ether, diethyleneglycol methylethyl ether, methyl 3-methoxypropionate, ethyl 3-ethoxypropionate, N,N-dimethylformamide, acetic acid, and water. The solvent may be one of them or may be a mixture of two or more of them.

For synthesis of the copolymer (A) and copolymer (C), known polymerization initiators can be used. Examples of the polymerization initiators include compounds that generate radicals by heat, azo-based initiators such as azo-bis-isobutyronitrile, and peroxide-based initiators such as benzoyl peroxide. In the radical polymerization reaction, an adequate amount of a chain transfer agent such as thioglycolic acid, may be added to regulate the molecular weight of the copolymer to be generated.

It is preferable that the copolymer (A) and copolymer (C) have a weight average molecular weight in a range of 1,000 to 100,000 defined by the GPC analysis using polyethylene oxide as a standard. This is because a developing time required for dissolving an exposed portion in an alkali developer is appropriate and the surface of a film hardly gets rough at the time of development. In addition, it is more preferable that the weight average molecular weight be in a range of 1,000 to 50,000 because the developing time for dissolving an unexposed portion in an alkali developer is appropriate, the film surface hardly gets rough at the time of development, and a residue from the development is in an extremely small amount. Further, it is particularly preferable that the weight average molecular weight be in a range of 1,500 to 20,000 because of the same reasons.

The weight average molecular weight of the copolymer (A) and copolymer (C) can be measured by using polyethylene oxide with a molecular weight of 1,000 to 510,000 (e.g., TSK standard, manufactured by Tosoh Corporation) as a polyethylene oxide standard, Shodex KD-806 M (manufactured by Showa Denko K.K.) as a column, and DMF as a mobile phase.

It should be noted that the composition of each of the copolymer (A) and the copolymer (C) in the photosensitive polymer composition of the invention can be estimated as follows: for example, when each of the copolymer (A) and the copolymer (C) thermally decomposes, the composition of each of the copolymers is estimated from monomer components detected by the GC-MS of a gas produced by the thermal decomposition.

In addition, the photosensitive polymer composition of the invention preferably has such property as described below: when a coating film which is formed by spin-coating a solution of a component except the 1,2-quinone diazide compound and heating the solution at 120° C. for 30 minutes and which has a thickness of 0.01 to 100 μm is immersed in, for example, a 2.38-wt % aqueous solution of tetramethylammonium hydroxide at about 25° C. for 5 minutes, and is then rinsed with pure water, the component dissolves in an alkali to such an extent that the coating film does not remain.

<1-5. Storage of Photosensitive Polymer Composition>

The photosensitive polymer composition of the invention is preferably stored at a temperature in the range of −30° C. to 25° C. while being shielded from light because the stability of the composition over time becomes favorable. The temperature at which the composition is stored is more preferably −20° C. to 10° C. because no precipitate is produced.

<1-6. Effect>

The photosensitive polymer composition has various characteristics generally requested of a patterned transparent film and insulating film such as high solvent resistance, high water resistance, high acid resistance, high alkali resistance, high heat resistance, high transparency, low dielectric property, and adhesiveness with a ground.

The photosensitive polymer composition of the invention has high radiation sensitivity and is excellent in solvent resistance, water resistance, acid resistance, alkali resistance, thermal resistance, transparency, and low dielectric property. Because the photosensitive polymer composition has high radiation sensitivity, in the production thereof, effects of reduction of exposing time, or reduction of developing time can be obtained. In addition, when a transparent film is produced using the positive photosensitive polymer composition, a rough surface on the polymer film is hardly caused even after carrying out an after-treatment of production of the transparent film such as immersion in a solvent, an acidic solution, and an alkali solution or contact therewith, and a thermal treatment. As a result, an increase in optical transmittance of the transparent film and also an improvement in display quality of a display device using the transparent film can be provided.

### 2. Patterned Transparent Film of the Invention

A patterned transparent film of the invention is a film obtained by subjecting an applied film of the above-mentioned photosensitive polymer composition to exposure through a mask having openings corresponding to a desired pattern, development, and baking. Further, in the patterned transparent film, postexposure is preferably performed between the development and the baking from the viewpoint of an improvement in transparency of the patterned transparent film. The postexposure can be omitted depending on the need for improving the transparency of the patterned transparent film. The photosensitive polymer composition is suitable to form a transparent polymer film. The resulting patterned transparent polymer film shows a comparatively high resolution at the time of patterning, so it is optimum for the formation of a patterned transparent film with a small pore with 10 μm or less. The patterned transparent film is preferably used as an insulating film. Here, the term “insulating film” refers to, for example, a film (interlayer insulating film) provided for insulation between the wirings arranged in layers.

The patterned transparent film can be formed by the conventional method, which is used in the formation of a polymer film in the field of resist technology. For example, it can be formed as follows.

(1) Forming the Applied Film

First, the photosensitive polymer composition of the invention is applied on a substrate made of glass or the like by the conventionally known method such as a spin-coating method, a roll-coating method, or a slit-coating method, whereby forming the applied film is formed. Subsequently, the applied film made of the photosensitive polymer composition on the substrate is dried by a hot plate or an oven. In general, the applied film is dried at 60 to 150° C. for 1 to 10 minutes. Examples of the substrate include: transparent glass substrates such as a white glass plate, a blue glass plate, a silica-coated blue glass plate; synthetic polymer sheets, films, or substrates, such as those made of polycarbonate, polyether sulfone, polyester, acrylic polymer, vinyl chloride polymer, aromatic polyamide polymer, polyamide imide, and polyimide; metal substrates such as an aluminum plate, a copper plate, a nickel plate, and a stainless steel plate; ceramic plates; and semiconductor substrates having opto-electric conversion elements. Those substrates may be subjected to any processing such as a chemical treatment with a silane coupling agent or the like, a plasma treatment, an ion-plating, a sputtering, a chemical vapor deposition, and a vacuum deposition.

(2) Exposure

The dried applied film on the substrate is irradiated with a radial ray such as UV-ray or the like through a mask with a desired pattern form. The irradiation conditions may depend on the kind of the photosensitizing agent in the photosensitive polymer composition. For example, when the photosensitizing agent is the 1,2-quinone diazide compound (B), the irradiation is suitably carried out by i-ray at 5 to 700 mJ/cm². The 1,2-quinone diazide compound (B) located on the UV-irradiated portion is converted into indene carboxylic acid to be in a state of being quickly dissolved in a developing solution.

(3) Developing

The film irradiated with a radial ray may be developed using a developing solution such as an alkali solution. The development allows the irradiated portion of the film to be dissolved in the developing solution. A developing method may be, but not particularly limited to, a dip-development, a paddle-development, or a shower-development. The developed film is sufficiently rinsed with pure water.

The above developing solution is preferably an alkali solution. Specific example of alkali in the alkali solution include tetra-methyl ammonium hydroxide, tetra-ethyl ammonium hydroxide, 2-hydroxy ethyl trimethyl ammonium hydroxide, sodium carbonate, sodium hydrogen carbonate, potassium carbonate, potassium hydrogen carbonate, sodium hydroxide, and potassium hydroxide. In addition, as a developing solution, any of these aqueous alkali solutions is suitably used. In other words, examples of the developing solutions include: organic alkali solutions such as those of tetra-methyl ammonium hydroxide, tetra-ethyl ammonium hydroxide, and 2-hydroxyethyl trimethyl ammonium hydroxide; and aqueous inorganic alkali solutions such as those of sodium carbonate, sodium hydroxide, and potassium hydroxide.

The developing solution may be added with methanol, ethanol, or a surfactant for a reduction in developing residue and a suitable pattern formation. For example, the surfactant may be one selected from the group consisting of anionic, cationic, and nonionic surfactants. Of those, in particular, a nonionic polyoxyethylene alkyl ether is preferably added in terms of improving resolution.

(4) Post Exposure

After development, the whole surface of the film on the substrate is irradiated again with a certain radial ray where necessary. For example, when the radial ray is UV-ray, the irradiation thereof at a strength of 100 to 1,000 mJ/cm² is carried out.

(5) Baking

The film on the substrate, which has been irradiated again with the radial ray, is baked at 180 to 250° C. for 10 to 120 minutes.

The transparent film which has been desirably patterned (patterned transparent film) thus obtained may be used as a patterned insulating film. The hole formed in the insulating film is preferably in the shape of a square, a rectangle, a circle, or an oval when viewed directly from above. Further, a transparent electrode may be formed on the insulating film and the patterning may be then performed by etching, and then, a film to be subjected to orientation-processing may be further formed. The insulating film has a high sputtering resistance, so the appearance of wrinkles does not occur on the insulating film even after forming the transparent electrode and high transparency can be thus retained.

### 3. Display Device of the Invention

A display device of the invention includes the above-mentioned patterned transparent film of the invention. The display device of the invention can be constituted in the same manner as in a known display device except that the above-mentioned patterned transparent film is used as a film based on the photosensitive polymer composition. For example, the patterned transparent film is used in a display device using a liquid crystal and the like. For example, the display device can be produced such that a device substrate on which a transparent film or an insulating film being patterned on the substrate as described above and a color filter substrate provided as an opposite substrate are aligned and pressure-bonded, followed by subjecting to a thermal treatment and combining the substrates together. Subsequently, a liquid crystal is injected into the space between the substrates facing each other, followed by sealing an inlet to thereby produce the display device.

Alternatively, the display device may be one produced by layering the device substrates together after dispersing the liquid crystal on the device substrate and then sealing the liquid crystal between the layered device substrates to prevent the leakage of the liquid crystal. The display device may be a display device produced by such a method described above.

Consequently, the display device of the invention can be formed into the liquid crystal display device including the insulating film having an excellent transparency, which is formed of the photosensitive polymer composition. In addition, the liquid crystal used in the liquid crystal display device (i.e., the liquid crystal compound and the liquid crystal composition) may be, but not particularly limited to, any of liquid crystal compound and a liquid crystal composition.

The display device of the invention shows high display quality because the display device has the patterned transparent film excellent in optical transmittance obtained by using the above-mentioned photosensitive polymer composition.

Hereinafter, the invention will be described more specifically by way of examples. However, the invention is not limited by these examples.

Each component of the compounds used in synthesis examples and comparative synthesis examples is described.

Polymerization Solvent:

Methyl 3-methoxy propionate,
Monomer (a1):

Methoxypolyethylene glycol methacrylate,

Ethoxypolyethylene glycol methacrylate,

Monomer (a2):

4-hydroxyphenyl vinyl ketone,

Glycidyl methacrylate,

3-methacryloxypropyl trimethoxy silane,

(3-ethyl-3-oxetanyl)methyl acrylate,

Methacrylic acid,

Dicyclopentanyl methacrylate,

N-phenyl maleimide,

Styrene,

N-cyclohexyl maleimide,

Methyl methacrylate,

### Polymerization Initiator:

2,2′-azobis(2,4-dimethyl valeronitrile)

### Synthesis Example 1

### Synthesis of Copolymer (A1)

Into a four-necked flask equipped with a stirring device, loaded were methyl 3-methoxy propionate as a polymerization solvent, methoxypolyethylene glycol methacrylate as the monomer (a1), 4-hydroxyphenyl vinyl ketone, glycidyl methacrylate, 3-methacryloxypropyl trimethoxy silane, and (3-ethyl-3-oxetanyl)methyl acrylate as the monomer (a2), 2,2′-azobis(2,4-dimethyl valeronitrile) as a polymerization initiator at the following weights, and a polymerization was performed by heating for 4 hours at a polymerization temperature of 80° C.

| | | |
|---|---|---|
| Methyl 3-methoxy propionate | 200.0 | g |
| Methoxypolyethylene glycol methacrylate | 10.0 | g |
| 4-hydroxyphenyl vinyl ketone | 30.0 | g |
| Glycidyl methacrylate | 35.0 | g |
| 3-methacryloxypropyl trimethoxy silane | 15.0 | g |
| (3-ethyl-3-oxetanyl)methyl acrylate | 10.0 | g |
| 2,2′-azobis(2,4-dimethyl valeronitrile) | 5.0 | g |

The reaction solution was cooled to room temperature, whereby the copolymer (A1) was obtained.

Part of the solution was sampled, and the weight average molecular weight of the copolymer was measured by GPC analysis (polyethylene oxide standard). As a result, the weight average molecular weight was 5,500.

### Synthesis Example 2

### Synthesis of Copolymer (A2)

In the same manner as in Synthesis Example 1, the following components were loaded at the following weights, and a polymerization was performed.

| | | |
|---|---|---|
| Methyl 3-methoxypropionate | 200.0 | g |
| Methoxypolyethylene glycol methacrylate | 10.0 | g |
| Methacrylic acid | 30.0 | g |
| Dicyclopentanyl methacrylate | 30.0 | g |
| N-phenylmaleimide | 30.0 | g |
| 2,2′-azobis(2,4-dimethylvaleronitrile) | 5.0 | g |

The resultant was treated in the same manner as in Synthesis Example 1, whereby the copolymer (A2) was obtained. The weight average molecular weight of the copolymer determined by GPC analysis (polyethylene oxide standard) was 5,000.

### Synthesis Example 3

### Synthesis of Copolymer (A3)

In the same manner as in Synthesis Example 1, the following components were loaded at the following weights, and a polymerization was performed.

| | | |
|---|---|---|
| Methyl 3-methoxypropionate | 200.0 | g |
| Methoxypolyethylene glycol methacrylate | 10.0 | g |
| 4-hydroxyphenyl vinyl ketone | 20.0 | g |
| Glycidyl methacrylate | 70.0 | g |
| 2,2′-azobis(2,4-dimethylvaleronitrile) | 5.0 | g |

The resultant was treated in the same manner as in Synthesis Example 1, whereby the copolymer (A3) was obtained. The weight average molecular weight of the copolymer determined by GPC analysis (polyethylene oxide standard) was 5,700.

### Synthesis Example 4

### Synthesis of Copolymer (A4)

In the same manner as in Synthesis Example 1, the following components were loaded at the following weights, and a polymerization was performed.

| | | |
|---|---|---|
| Methyl 3-methoxypropionate | 200.0 | g |
| Ethoxypolyethylene glycol methacrylate | 10.0 | g |
| 4-hydroxyphenyl vinyl ketone | 30.0 | g |
| Dicyclopentanyl methacrylate | 30.0 | g |
| N-phenylmaleimide | 30.0 | g |
| 2,2′-azobis(2,4-dimethylvaleronitrile) | 5.0 | g |

The resultant was treated in the same manner as in Synthesis Example 1, whereby the copolymer (A4) was obtained. The weight average molecular weight of the copolymer determined by GPC analysis (polyethylene oxide standard) was 5,100.

### Synthesis Example 5

### Synthesis of Copolymer (A5)

In the same manner as in Synthesis Example 1, the following components were loaded at the following weights, and a polymerization was performed.

| | | |
|---|---|---|
| Methyl 3-methoxypropionate | 200.0 | g |
| Methoxypolyethylene glycol methacrylate | 20.0 | g |
| Methacrylic acid | 30.0 | g |
| 3-methacryloxypropyl trimethoxy silane | 30.0 | g |
| N-phenylmaleimide | 20.0 | g |
| 2,2′-azobis(2,4-dimethylvaleronitrile) | 5.0 | g |

The resultant was treated in the same manner as in Synthesis Example 1, whereby the copolymer (A5) was obtained. The weight average molecular weight of the copolymer determined by GPC analysis (polyethylene oxide standard) was 4,700.

### Synthesis Example 7

### Synthesis of Copolymer (C1)

In the same manner as in Synthesis Example 1, the following components were loaded at the following weights, and a polymerization was performed.

| | | |
|---|---|---|
| Methyl 3-methoxypropionate | 200.0 | g |
| 4-hydroxyphenyl vinyl ketone | 10.0 | g |
| Glycidyl methacrylate | 30.0 | g |
| 3-methacryloxypropyl trimethoxy silane | 30.0 | g |
| Styrene | 30.0 | g |
| 2,2′-azobis(2,4-dimethylvaleronitrile) | 5.0 | g |

The resultant was treated in the same manner as in Synthesis Example 1, whereby the copolymer (C1) was obtained. The weight average molecular weight of the copolymer determined by GPC analysis (polyethylene oxide standard) was 6,900.

### Synthesis Example 8

### Synthesis of Copolymer (C2)

In the same manner as in Synthesis Example 1, the following components were loaded at the following weights, and a polymerization was performed.

| | | |
|---|---|---|
| Methyl 3-methoxypropionate | 200.0 | g |
| Methacrylic acid | 30.0 | g |
| Dicyclopentanyl methacrylate | 40.0 | g |
| N-cyclohexyl maleimide | 30.0 | g |
| 2,2′-azobis(2,4-dimethylvaleronitrile) | 5.0 | g |

The resultant was treated in the same manner as in Synthesis Example 1, whereby the copolymer (C2) was obtained. The weight average molecular weight of the copolymer determined by GPC analysis (polyethylene oxide standard) was 7,600.

### Synthesis Example 9

### Synthesis of Copolymer (A6)

In the same manner as in Synthesis Example 1, the following components were loaded at the following weights, and a polymerization was performed.

| | | |
|---|---|---|
| Methyl 3-methoxypropionate | 200.0 | g |
| Methoxypolyethylene glycol methacrylate | 10.0 | g |
| 4-hydroxyphenyl vinyl ketone | 20.0 | g |
| Glycidyl methacrylate | 60.0 | g |
| N-cyclohexyl maleimide | 10.0 | g |
| 2,2′-azobis(2,4-dimethylvaleronitrile) | 5.0 | g |

The resultant was treated in the same manner as in Synthesis Example 1, whereby the copolymer (A6) was obtained. The weight average molecular weight of the copolymer determined by GPC analysis (polyethylene oxide standard) was 7,300.

### Synthesis Example 10

### Synthesis of Copolymer (A7)

In the same manner as in Synthesis Example 1, the following components were loaded at the following weights, and a polymerization was performed.

| | | |
|---|---|---|
| Methyl 3-methoxypropionate | 200.0 | g |
| Methoxypolyethylene glycol methacrylate | 10.0 | g |
| 4-hydroxyphenyl vinyl ketone | 10.0 | g |
| Glycidyl methacrylate | 50.0 | g |
| Dicyclopentanyl methacrylate | 15.0 | g |
| N-cyclohexyl maleimide | 15.0 | g |
| 2,2′-azobis(2,4-dimethylvaleronitrile) | 5.0 | g |

The resultant was treated in the same manner as in Synthesis Example 1, whereby the copolymer (A7) was obtained. The weight average molecular weight of the copolymer determined by GPC analysis (polyethylene oxide standard) was 8,000.

### Comparative Synthesis Example 1

### Synthesis of Comparative Copolymer (D1)

In the same manner as in Synthesis Example 1, the following components were loaded at the following weights, and a polymerization was performed.

| | | |
|---|---|---|
| Methyl 3-methoxypropionate | 200.0 | g |
| 4-hydroxyphenyl vinyl ketone | 10.0 | g |
| Methacrylic acid | 20.0 | g |
| Glycidyl methacrylate | 40.0 | g |
| 3-methacryloxypropyl trimethoxy silane | 20.0 | g |
| (3-ethyl-3-oxetanyl)methyl acrylate | 10.0 | g |
| 2,2′-azobis(2,4-dimethylvaleronitrile) | 5.0 | g |

The resultant was treated in the same manner as in Synthesis Example 1, whereby the comparative copolymer (D1) was obtained. The weight average molecular weight of the copolymer determined by GPC analysis (polyethylene oxide standard) was 6,200.

### Comparative Synthesis Example 2

### Synthesis of Comparative Copolymer (D2)

In the same manner as in Synthesis Example 1, the following components were loaded at the following weights, and a polymerization was performed.

| | | |
|---|---|---|
| Methyl 3-methoxypropionate | 200.0 | g |
| 4-hydroxyphenyl vinyl ketone | 20.0 | g |
| Glycidyl acrylate | 60.0 | g |
| N-phenylmaleimide | 20.0 | g |
| 2,2′-azobis(2,4-dimethylvaleronitrile) | 5.0 | g |

The resultant was treated in the same manner as in Synthesis Example 1, whereby the comparative copolymer (D2) was obtained. The weight average molecular weight of the copolymer determined by GPC analysis (polyethylene oxide standard) was 5,900.

### Comparative Synthesis Example 3

### Synthesis of Comparative Copolymer (D3)

In the same manner as in Synthesis Example 1, the following components were loaded at the following weights, and a polymerization was performed.

| | | |
|---|---|---|
| Methyl 3-methoxypropionate | 200.0 | g |
| 4-hydroxyphenyl vinyl ketone | 20.0 | g |
| Glycidyl methacrylate | 65.0 | g |
| Methyl methacrylate | 15.0 | g |
| 2,2′-azobis(2,4-dimethylvaleronitrile) | 5.0 | g |

The resultant was treated in the same manner as in Synthesis Example 1, whereby the comparative copolymer (D3) was obtained. The weight average molecular weight of the copolymer determined by GPC analysis (polyethylene oxide standard) was 6,800.

### Example 1

### Production of Positive Photosensitive Polymer Composition

A positive photosensitive polymer composition was obtained by mixing and dissolving: the copolymer (A1) obtained in Synthesis Example 1; a condensation product of 4,4′-[1-[4-[1-[4-hydroxyphenyl]-1-methylethyl]phenyl]ethylidene]bisphenol and 1,2-naphthoquinone diazide-5-chlorsulfonate (an average esterification rate of 58%, hereinafter referred to as “PAD”); a fluorine-based surfactant, MEGAFACE R-08, manufactured by Dai-Nippon Ink Chemicals (hereinafter, abbreviated as “R-08”) as an additive; and methyl 3-methoxypropionate as a solvent in weights as described below.

| | | |
|---|---|---|
| Methyl 3-methoxypropionate | 1.40 | g |
| 30 wt % solution of copolymer (A1) | 10.00 | g |
| PAD | 0.60 | g |
| R-08 | 0.006 | g |

[Method of Evaluating Positive Photosensitive Polymer Composition]

(1) Formation of Patterned Transparent Film

The positive photosensitive polymer composition synthesized in Example 1 was spin-coated on a glass substrate at 500 to 800 rpm for 10 seconds and then dried on a hot plate at 100° C. for 2 minutes. The substrate was exposed with an exposure gap of 100 μm through a mask for hole-pattern formation in the air using the Proximity Exposure System TME-150 PRC, manufactured by Topcon Co., Ltd. with g, h, and i rays taken out by cutting rays of 350 nm or less through a wavelength cut filter. The amount of light exposure was measured using a totalizing actinometer UIT-102 and a photometer UVD-365 PD, manufactured by Ushio Inc., resulting in 50 to 150 mJ/cm². The glass substrate after the exposure was developed by dipping in an aqueous solution of 0.4 wt % of tetramethyl ammonium hydroxide at 25° C. for 60 seconds, thereby removing a polymer composition from the exposed portion. The substrate after the development was washed with pure water for 60 seconds and then dried on a hot plate at 100° C. for 2 minutes. The whole surface of the substrate was exposed in the exposure system at a light exposure of 300 mJ/cm² without using any mask and then post-baked in an oven at 230° C. for 30 minutes, thereby forming a patterned transparent film with a film thickness of 3 μm. The film thickness was measured as an average of film thicknesses measured at three different points using a probe-type thickness tester α-Step 200, manufactured by KLA-Tencor Japan Co., Ltd.

(2) Residual Film Rate after Development

The film thickness was measured before and after the development, and residual film rate after development was calculated from the following equation.

{(Film thickness after development)/(film thickness before development)}×100(%)

(3) Sensitivity to Radiation

The substrate of the patterned transparent film after the development obtained in the above section (1) was observed with an optical microscope at a magnification of 400 times, and the amount of light exposure in which a 10-μm size hole pattern was formed with a 10-μm mask size hole pattern was identified.

(3) Resolution

The substrate of the patterned transparent film after post-baking obtained in the above item (1) was observed by an optical microscope at a magnification of 400 times to confirm a mask size where the glass is exposed on the bottom of the hole pattern.

(4) Transparency

An optical transmittance of the substrate of the patterned transparent film after post-baking obtained in the above item (1) at a wavelength of 400 nm was measured by using TC-1800 (manufactured by Tokyo Denshoku Co. Ltd.) as a reference on a glass substrate without forming a transparent film.

(5) Solvent Resistance

The patterned transparent film obtained in the above item (1) was dipped in N-methyl-2-pyrolidone at 100° C. for 5 minutes and the change of a film thickness was measured. The film thickness was measured before and after the dipping and the change rate of a film thickness was calculated from the following equation:

{(Film thickness after dipping)/(film thickness before dipping)}×100(%)

When the change rate of the film thickness is −2 to 2%, it is judged good. When it exceeds 2% by swelling or is less than −2% by dissolving, it is judged failure.

(6) Acid Resistance

The patterned transparent film obtained in the above item (1) was dipped in hydrochloric acid/nitric acid/water=4/2/4 (weight ratio) at 50° C. for 3 minutes and the change of a film thickness was measured. The film thicknesses were measured before and after the dipping and the change rate of a film thickness was calculated from the following equation:

{(Film thickness after dipping)/(film thickness before dipping)}×100(%)

When the change rate of the film thickness is −2 to 2%, it is judged good. When it exceeds 2% by swelling or is less than −2% by dissolving, it is judged failure.

(7) Alkali Resistance

The patterned transparent film obtained in the above item (1) was dipped in 5% potassium hydroxide aqueous solution at 60° C. for 10 minutes and the change of a film thickness was measured. The film thickness was measured before and after the dipping and the change rate of a film thickness was calculated from the following equation:

{(Film thickness after dipping)/(film thickness before dipping)}×100(%)

When the change rate of the film thickness is −2 to 2%, it is judged good. When it exceeds 2% by swelling or is less than −2% by dissolving, it is judged failure.

(8) Thermal Resistance

The substrate of the patterned transparent film obtained in the above item (1) was further baked in the oven at 230° C. for 1 hour and the optical transmittance thereof was then measured in a manner similar to the above item (4) before and after the heating. The optical transmittance after the post-baking (before the additional baking) was defined as T1 and the optical transmittance after the additional baking was defined as T2. It can be judged more excellent as a lowering of the optical transmittance from the optical transmittance after the post baking to the optical transmittance after the additional baking is small. In addition, the film thickness was measured after and before the heating. Then, the change rate of the film thickness was calculated from the following equation.

{(Film thickness after additional baking)/(film thickness after post baking)}×100(%)

(9) Adhesiveness

The patterned transparent film obtained in the above item (1) was evaluated by a crosscut peeling test (crosscut test). The results of the evaluation were expressed by the number of the remaining grids after tape-peeling among 100 grids (1 mm square).

(10) Sputtering Resistance

On the substrate of the patterned transparent film obtained in the above item (1), a transparent electrode made of indium tin oxide (ITO) was formed in a film thickness of 150 nm by sputtering at 200° C. After that, the temperature was returned to room temperature and the presence or absence of a wrinkle on the film surface was observed by visual observation. The sputtering resistance was judged good (G) when no wrinkle was formed on the film surface. On the other hand, it was judged no good (NG) when a wrinkle was formed on the film surface.

(11) Relative Dielectric Constant

Electrodes were produced above and below the transparent film, and the relative dielectric constant of the resultant was measured with an LCR meter (4284A) manufactured by Agilent Technologies. The evaluation was performed at 1 kHz.

With respect to the positive photosensitive polymer composition synthesized in Example 1, the results obtained by the aforementioned evaluation method are listed in Table 1.

TABLE 1

| | Exam- | Exam- | Exam- | Exam- | Exam- |
|---|---|---|---|---|---|
| | ple 1 | ple 2 | ple 3 | ple 4 | ple 5 |
| Residual film rate | 94.8 | 94.2 | 94.0 | 94.5 | 94.7 |
| after development | | | | | |
| (%) | | | | | |
| Radiation | 120 | 90 | 80 | 100 | 80 |
| sensitivity | | | | | |
| (mJ/cm²) | | | | | |
| Resolution | 7 | 7 | 6 | 7 | 6 |
| (μm) | | | | | |
| Film thickness | 3.10 | 3.00 | 2.99 | 3.03 | 3.00 |
| after post baking | | | | | |
| (μm) | | | | | |
| Optical | 97.9 | 98.0 | 97.5 | 97.2 | 98.1 |
| transmittance T1 | | | | | |
| (%) | | | | | |
| Solvent resistance | 99.9 | 100 | 100 | 99.9 | 99.9 |
| (%) | | | | | |
| Acid resistance | 100 | 101 | 99.9 | 100 | 100 |
| (%) | | | | | |
| Alkali resistance | 100 | 101 | 100 | 101 | 100 |
| (%) | | | | | |
| Optical | 97.5 | 97.5 | 97.0 | 96.7 | 97.7 |
| transmittance T2 | | | | | |
| (%) | | | | | |
| Film thickness | 3.07 | 2.95 | 2.94 | 2.99 | 2.97 |
| after additional | | | | | |
| baking | | | | | |
| (μm) | | | | | |
| Thermal resistance | 99.0 | 98.3 | 98.3 | 98.7 | 99.0 |
| (change rate of | | | | | |
| film thickness, %) | | | | | |
| Adhesiveness | 100 | 100 | 100 | 100 | 100 |
| Sputtering | G | G | G | G | G |
| resistance | | | | | |
| Relative dielectric | 3.3 | 3.2 | 3.6 | 3.6 | 3.7 |
| constant | | | | | |

### Example 2

A positive photosensitive polymer composition was prepared in the same manner as in Example 1 except that a mixture containing the copolymer (A2) obtained in Synthesis Example 2 and the copolymer (C1) obtained in Synthesis Example 7 at a weight ratio of 1:1 was used instead of the copolymer (A1) used in Example 1. Then, the composition was evaluated in the same manner as in Example 1. Table 1 shows the results.

### Example 3

A positive photosensitive polymer composition was prepared in the same manner as in Example 1 except that a mixture containing the copolymer (A3) obtained in Synthesis Example 3 and the copolymer (C2) obtained in Synthesis Example 8 at a weight ratio of 1:1 was used instead of the copolymer (A1) used in Example 1. Then, the composition was evaluated in the same manner as in Example 1. Table 1 shows the results.

### Example 4

A positive photosensitive polymer composition was prepared in the same manner as in Example 1 except that a mixture containing the copolymer (A4) obtained in Synthesis Example 4 and the copolymer (A6) obtained in Synthesis Example 9 at a weight ratio of 1:1 was used instead of the copolymer (A1) used in Example 1. Then, the composition was evaluated in the same manner as in Example 1. Table 1 shows the results.

### Example 5

A positive photosensitive polymer composition was prepared in the same manner as in Example 1 except that a mixture containing the copolymer (A5) obtained in Synthesis Example 5 and the copolymer (A7) obtained in Synthesis Example 10 at a weight ratio of 1:1 was used instead of the copolymer (A1) used in Example 1. Then, the composition was evaluated in the same manner as in Example 1. Table 1 shows the results.

### Comparative Example 1

A positive photosensitive polymer composition was prepared in the same manner as in Example 1 except that the comparative copolymer (D1) obtained in Comparative Synthesis Example 1 was used instead of the copolymer (A1) used in Example 1. Then, the composition was evaluated in the same manner as in Example 1. Table 2 shows the results.

### Comparative Example 2

A positive photosensitive polymer composition was prepared in the same manner as in Example 1 except that a mixture containing the comparative copolymer (D2) obtained in Comparative Synthesis Example 2 and the copolymer (C2) obtained in Synthesis Example 8 at a weight ratio of 1:1 was used instead of the copolymer (A1) used in Example 1. Then, the composition was evaluated in the same manner as in Example 1. Table 2 shows the results.

### Comparative Example 3

A positive photosensitive polymer composition was prepared in the same manner as in Example 1 except that a mixture containing the comparative copolymer (D3) obtained in Comparative Synthesis Example 3 and the copolymer (C1) obtained in Synthesis Example 7 at a weight ratio of 1:1 was used instead of the copolymer (A1) used in Example 1. Then, the composition was evaluated in the same manner as in Example 1. Table 2 shows the results.

Comparative Examples 1 to 3 show that the positive photosensitive polymer compositions of Examples 1 to 5 are each excellent in sensitivity to radiation. In addition, Comparative Examples 2 and 3 show that the positive photosensitive polymer compositions of Examples 1 to 5 are each excellent in optical transmittance, and each exert an excellent in suppressing effect on a reduction in its optical transmittance due to heating. Further, Comparative Examples 1 and 3 show that the positive photosensitive polymer compositions of Examples 1 to 5 are each excellent in sputtering resistance.

The positive photosensitive polymer composition of the invention can be used in, for example, a liquid crystal display device.

TABLE 2

| | Comparative | Comparative | Comparative |
|---|---|---|---|
| | Example 1 | Example 2 | Example 3 |
| Residual film rate | 95.3 | 95.0 | 94.0 |
| after development | | | |
| (%) | | | |
| Radiation | 150 | 150 | 160 |
| sensitivity | | | |
| (mJ/cm²) | | | |
| Resolution | 7 | 7 | 8 |
| (μm) | | | |
| Film thickness | 3.03 | 3.00 | 3.02 |
| after post baking | | | |
| (μm) | | | |
| Optical | 98.1 | 96.9 | 92.9 |
| transmittance T1 | | | |
| (%) | | | |
| Solvent resistance | 99.8 | 99.5 | 100 |
| (%) | | | |
| Acid resistance | 101 | 100 | 101 |
| (%) | | | |
| Alkali resistance | 101 | 101 | 102 |
| (%) | | | |
| Optical | 97.4 | 95.5 | 90.2 |
| transmittance T2 | | | |
| (%) | | | |
| Film thickness | 2.98 | 2.94 | 2.94 |
| after additional | | | |
| baking | | | |
| (μm) | | | |
| Thermal resistance | 98.3 | 98.0 | 97.4 |
| (change rate of | | | |
| film thickness, %) | | | |
| Adhesiveness | 100 | 100 | 100 |
| Spattering | NG | G | NG |
| resistance | | | |
| Relative dielectric | 3.4 | 3.6 | 3.7 |
| constant | | | |

1. A photosensitive polymer composition, comprising:
a copolymer (A) obtained by polymerizing a radical polymerizable monomer (a1) represented by the following formula (I) and another radical polymerizable monomer (a2); and
a 1,2-quinone diazide compound (B): 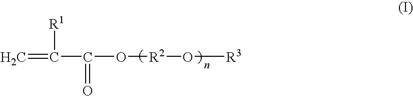
where R¹ represents hydrogen or an alkyl group having 1 to 5 carbon atoms in which arbitrary hydrogen may be replaced by fluorine, R² represents an alkylene group having 1 to 5 carbon atoms, R³ represents an alkyl group having 1 to 10 carbon atoms, and n represents an integer of 1 to 30.

2. The photosensitive polymer composition according to claim 1, wherein the radical polymerizable monomer (a1) comprises one or more kinds selected from the group consisting of methoxy polyethylene glycol (meth)acrylate, ethoxy polyethylene glycol (meth)acrylate, methoxy polypropylene glycol (meth)acrylate, and ethoxy polypropylene glycol (meth)acrylate.

3. The photosensitive polymer composition according to claim 1, wherein the radical polymerizable monomer (a2) comprises one or more kinds selected from the group consisting of a radical polymerizable monomer having an unsaturated carboxylic acid, a radical polymerizable monomer having an unsaturated carboxylic anhydride, a radical polymerizable monomer having a phenolic OH, a radical polymerizable monomer having an epoxy, a radical polymerizable monomer represented by the following formula (III), a radical polymerizable monomer containing an N-substituted maleimide, and a radical polymerizable monomer containing a dicyclopentanyl: 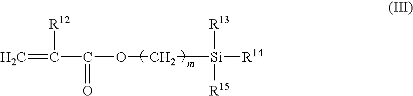
where R¹² represents hydrogen or an alkyl group having 1 to 5 carbon atoms in which arbitrary hydrogen may be replaced by fluorine, R¹³, R¹⁴, and R¹⁵ each represent a hydroxyl group, an alkyl group having 1 to 5 carbon atoms, an alkoxy group having 1 to 5 carbon atoms, or —O—(Si(CⱼH₂ⱼ₊₁)₂O)ₚSi(CₖH₂ₖ₊₁)₃, j represents an integer of 1 to 5, k represents an integer of 1 to 5, p represents 0 or an integer of 1 to 10, and m represents an integer of 1 to 5.

4. The photosensitive polymer composition according to claim 3, wherein the radical polymerizable monomer having an unsaturated carboxylic acid is (meth)acrylic acid.

5. The photosensitive polymer composition according to claim 3, wherein the radical polymerizable monomer having an unsaturated carboxylic anhydride is maleic anhydride.

6. The photosensitive polymer composition according claim 3, wherein the radical polymerizable monomer having a phenolic OH is one or both of hydroxystyrene and a compound represented by the following formula (II): 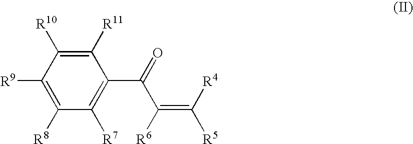
where R⁴, R⁵, and R⁶ each represent hydrogen or an alkyl group having 1 to 3 carbon atoms in which arbitrary hydrogen may be replaced by fluorine, R⁷, R⁸, R⁹, R¹⁰, and R¹¹ each represent hydrogen, a halogen, —CN, —CF₃, —OCF₃, —OH, an alkyl group having 1 to 5 carbon atoms in which arbitrary —CH₂— may be replaced by —COO—, —OCO—, or —CO— and arbitrary hydrogen may be replaced by a halogen, or an alkoxy group having 1 to 5 carbon atoms in which arbitrary hydrogen may be replaced by a halogen, provided that one or more of R⁷ to R¹¹ represents —OH.

7. The photosensitive polymer composition according to claim 6, wherein the compound represented by the formula (II) is 4-hydroxyphenyl vinyl ketone.

8. The photosensitive polymer composition according claim 3, wherein the radical polymerizable monomer having an epoxy is one or more kinds selected from the group consisting of glycidyl (meth)acrylate, methylglycidyl (meth)acrylate, 3,4-epoxycyclohexylmethyl (meth)acrylate, (3-methyl-3-oxetanyl)methyl (meth)acrylate, (3-ethyl-3-oxetanyl)methyl (meth)acrylate, (3-methyl-3-oxetanyl)ethyl (meth)acrylate, and (3-ethyl-3-oxetanyl)ethyl (meth)acrylate.

9. The photosensitive polymer composition according to claim 3, wherein the radical polymerizable monomer containing an N-substituted maleimide is one or more kinds selected from the group consisting of N-methylmaleimide, N-ethylmaleimide, N-butylmaleimide, N-cyclohexylmaleimide, N-benzylmaleimide, N-phenylmaleimide, N-(4-acetylphenyl)maleimide, N-(2,6-diethylphenyl)maleimide, N-(4-dimethylamino-3,5-dinitrophenyl)maleimide, N-(1-anilinonaphthyl-4)maleimide, N-[4-(2-benzoxazolyl)phenyl]maleimide, and N-(9-acridinyl)maleimide.

10. The photosensitive polymer composition according to claim 3, wherein the radical polymerizable monomer containing a dicyclopentanyl is dicyclopentanyl (meth)acrylate.

11. The photosensitive polymer composition according to claim 1, wherein the 1,2-quinone diazide compound (B) is a condensation product of 4,4′-[1-[4-[1-[4-hydroxyphenyl]-1-methylethyl]phenyl]ethylidene]bisphenol and 1,2-naphthoquinone diazide-5-sulfonic acid chloride.

12. The photosensitive polymer composition according to claim 1, further comprising a compound having an epoxy.

13. The photosensitive polymer composition according to claim 1, further comprising a copolymer (C) obtained by polymerizing two or more kinds of the radical polymerizable monomers (a2).

14. The photosensitive polymer composition according to claim 13, wherein the radical polymerizable monomers (a2) in the copolymer (C) include the radical polymerizable monomer (a2) according to claim 3.

15. The photosensitive polymer composition according to claim 1, further comprising a hindered phenol antioxidant.

16. A patterned transparent film obtained by exposure to an applied film of the photosensitive polymer composition according to claim 1 through a mask having openings in accordance with a desired pattern, development, and baking.

17. A patterned transparent film obtained by exposure to an applied film of the photosensitive polymer composition according to claim 1 through a mask having openings in accordance with a desired pattern, development, postexposure, and baking.

18. The patterned transparent film according to claim 16, wherein the patterned transparent film is an insulating film.

19. A display device comprising the patterned transparent film according to claim 16.

20. The patterned transparent film according to claim 17, wherein the patterned transparent film is an insulating film.

21. A display device comprising the patterned transparent film according to claim 17.

22. A display device comprising the patterned transparent film according to claim 18.
